(19) United States
(12) Patent Application Publication
(10) Pub. No.: US 2026/0324491 A1
(43) Pub. Date: Oct. 15, 2026

(54) SEMICONDUCTOR DEVICE AND SEMICONDUCTOR PACKAGE

(71) Applicant: InnoLux Corporation, Miao-Li County (TW)

(72) Inventors: Jui-Jen YUEH, Miao-Li County (TW); Chung-Wen YEN, Miao-Li County (TW); Ti-Chung CHANG, Miao-Li County (TW)

(73) Assignee: InnoLux Corporation, Miao-Li County (TW)

(21) Appl. No.: 19/466,486

(22) Filed: Feb. 1, 2026

(30) Foreign Application Priority Data
Mar. 26, 2025 (CN) 202510364706.4

(51) Int. Cl. H10W 72/90; H10F 39/90; H10W 90/00

(52) U.S. Cl. CPC H10W 72/934; H10F 39/90; H10W 72/936; H10W 90/792

(57) ABSTRACT

A semiconductor device includes a substrate and an interconnection layer. The substrate includes a device region and a peripheral region, and the peripheral region is adjacent to the device region. The interconnection layer is disposed on the substrate, and the interconnection layer includes a circuit structure overlapped with the device region and a first structure overlapped with the peripheral region. The first structure includes a plurality of first portions arranged in a first direction parallel to a normal direction of the substrate, and a plurality of second portions disposed between two adjacent ones of the first portions and arranged in a second direction perpendicular to the first direction. In a cross-sectional view, the first structure has a first rounded corner located between an inner side surface of one of the first portions and an inner side surface of one of the second portions.

### BACKGROUND OF THE DISCLOSURE

### Field of the Disclosure

The present disclosure relates to a semiconductor device, and more particularly to a semiconductor device having a specific design for protecting a circuit structure and a related semiconductor package.

### 2. DESCRIPTION OF THE PRIOR ART

During the manufacturing process of a semiconductor element, after completing circuit formation on a wafer substrate, the wafer is diced through a cutting process (e.g., blade cutting) to form a plurality of dies. However, under high-speed rotation of the blade during cutting, vibrations caused by mechanical cutting and electrostatic charges generated by high-speed friction may adversely affect the wafer, thereby degrading product quality.

### SUMMARY OF THE DISCLOSURE

One of objectives of the present disclosure is to provide a semiconductor device and a related semiconductor package, wherein by disposing a first structure having a rounded corner, the circuit structure of an interconnection layer may be protected to reduce damage to the circuit structure, thereby improving the quality and reliability of the semiconductor device.

An embodiment of the present disclosure provides a semiconductor device including a substrate and an interconnection layer. The substrate includes a device region and a peripheral region, and the peripheral region is adjacent to the device region. The interconnection layer is disposed on the substrate, and the interconnection layer includes a circuit structure overlapped with the device region and a first structure overlapped with the peripheral region. The first structure includes a plurality of first portions and a plurality of second portions, the plurality of first portions are arranged in a first direction parallel to a normal direction of the substrate, and the plurality of second portions are disposed between two adjacent ones of the plurality of first portions and arranged in a second direction perpendicular to the first direction. In a cross-sectional view, the first structure has a first rounded corner located between an inner side surface of one of the plurality of first portions and an inner side surface of one of plurality of the second portions.

An embodiment of the present disclosure provides a semiconductor package including a circuit substrate, an interposer, the semiconductor device described above, and a first semiconductor die. The interposer is disposed on the circuit substrate, and the interposer includes a first connection pad bonded on the circuit substrate. The semiconductor device is disposed on the interposer. The first semiconductor die is disposed on the interposer and electrically connected to the semiconductor device through the interposer. The first structure of the semiconductor device is not overlapped with the first connection pad in the first direction.

An embodiment of the present disclosure provides a semiconductor package including the semiconductor device described above, a molding layer, a redistribution layer, and a fourth semiconductor die. The molding layer surrounds the semiconductor device. The redistribution layer is disposed on a side of the semiconductor device and the molding layer, and the redistribution layer is electrically connected to the circuit structure and includes a fourth connection pad. The fourth semiconductor die is disposed on a side of the semiconductor device away from the redistribution layer and electrically connected to the redistribution layer through a via in the molding layer. The first structure of the semiconductor device is not overlapped with the fourth connection pad in the first direction.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a cross-sectional schematic diagram of a semiconductor device according to an embodiment of the present disclosure.

FIG. 2 is a top-view schematic diagram of a semiconductor device according to an embodiment of the present disclosure.

FIG. 3 is a schematic diagram illustrating a process of a semiconductor device according to an embodiment of the present disclosure.

FIG. 4 is a partially-enlarged schematic diagram of the semiconductor device shown in FIG. 1.

FIG. 5 is another partially-enlarged schematic diagram of the semiconductor device shown in FIG. 1.

FIG. 6 is a cross-sectional schematic diagram of a semiconductor device according to another embodiment of the present disclosure.

FIG. 7 is a cross-sectional schematic diagram of a semiconductor package according to a first embodiment of the present disclosure.

FIG. 8 is a cross-sectional schematic diagram of a semiconductor package according to a second embodiment of the present disclosure.

FIG. 9 is a cross-sectional schematic diagram of a semiconductor package according to a third embodiment of the present disclosure.

FIG. 10 is an enlarged schematic diagram of a third semiconductor die shown in FIG. 9.

FIG. 11 is a cross-sectional schematic diagram of a semiconductor package according to a fourth embodiment of the present disclosure.

### DETAILED DESCRIPTION

For purposes of illustrative clarity and being easily understood by the readers, it is noted that various drawings of this disclosure show a portion of the device or structure, and certain components in various drawings may not be drawn to scale.

The ordinal numbers used in the description and claims, such as “first”, “second”, “third”, etc., are used to describe elements, but they do not mean and represent that the element(s) have any previous ordinal numbers, nor do they represent the order of one element and another element, or the order of manufacturing methods.

It should be noted that the technical features in different embodiments described in the following can be replaced, recombined, or mixed with one another to constitute another embodiment without departing from the spirit of the present disclosure.

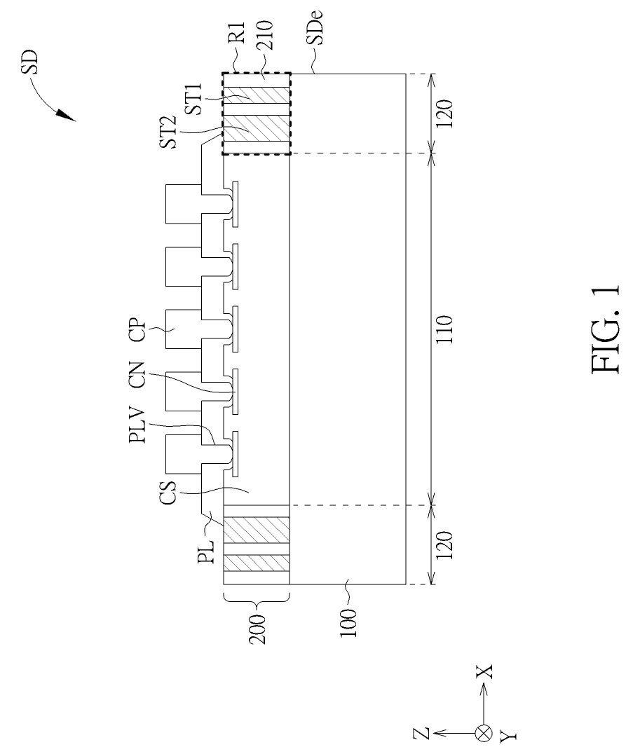

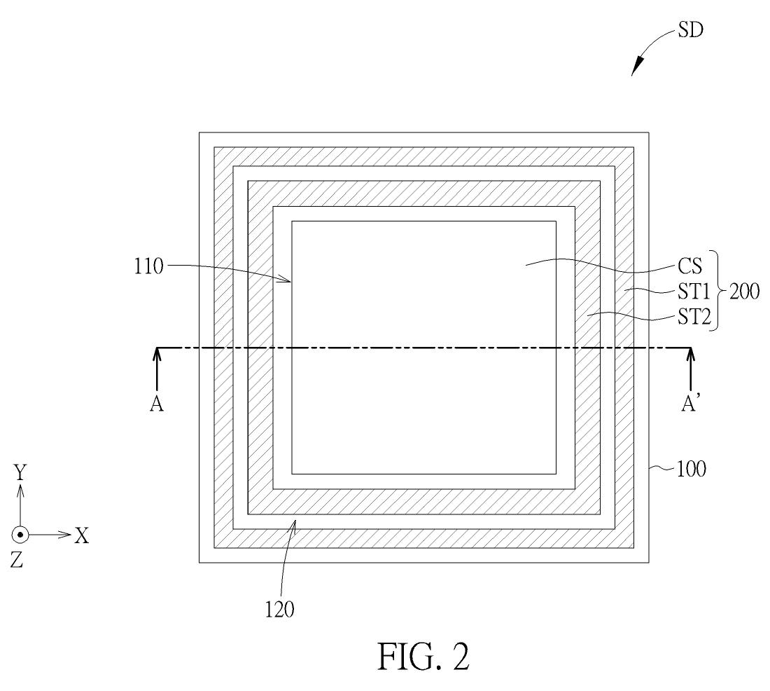

Refer to FIG. 1 and FIG. 2, wherein FIG. 2 schematically depicts only a portion of components of the semiconductor device, and FIG. 1 is a cross-sectional view corresponding to the section line A-A’ in FIG. 2. As shown in FIG. 1 and FIG. 2, a semiconductor device SD includes a substrate 100 and an interconnection layer 200. The substrate 100 includes a device region 110 and a peripheral region 120, wherein the peripheral region 120 is adjacent to the device region 110. For example, the peripheral region 120 is located around the device region 110. The material of the substrate 100 may include silicon (Si), silicon carbide (SiC), gallium arsenide (GaAs), sapphire, gallium nitride (GaN), quartz, glass, ceramic, or other suitable materials. The interconnection layer 200 is disposed on the substrate 100 and includes a circuit structure CS and a first structure ST1. The circuit structure CS is overlapped with the device region 110, and the first structure ST1 is overlapped with the peripheral region 120. The circuit structure CS is formed by at least one insulating layer and at least one conductive layer stacked along a direction Z on the substrate 100. For example, the circuit structure CS may be a redistribution structure configured to redistribute wiring and/or further increase the wiring fan-out area. For simplicity of the drawings, the circuit structure CS is represented as a rectangular block, and in regions outside the circuit structure CS, the at least one insulating layer of the interconnection layer 200 is integrally represented as an insulating layer 210. In the top view shown in FIG. 2, the first structure ST1 may extend along a direction X and a direction Y to form a closed pattern (e.g., a frame-shaped pattern) surrounding the circuit structure CS. The direction Z is parallel to a normal direction of the substrate 100 (e.g., a normal direction of the upper or lower surface of the substrate 100) and parallel to a top view direction of the semiconductor device SD. The direction Z is perpendicular to the direction X and the direction Y, and the direction X is perpendicular to the direction Y.

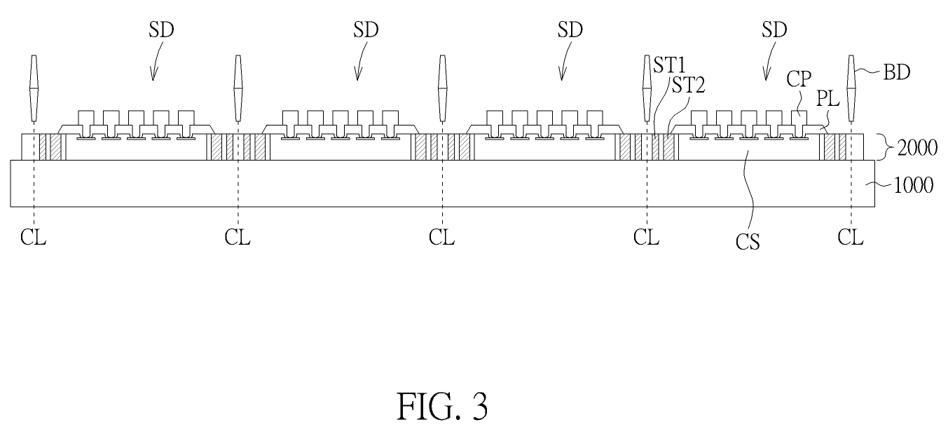

The first structure ST1 overlapping the peripheral region 120 is adjacent to an edge SDe of the semiconductor device SD, wherein the edge SDe corresponds to a position of a cutting line during a manufacturing process of the semiconductor device SD, for example, a cutting line CL shown in FIG. 3, wherein the cutting lines CL are the positions where cutting is performed in a singulation process of the semiconductor device. As shown in FIG. 3, during the manufacturing process of the semiconductor device SD, an interconnection layer 2000 is formed on a substrate 1000, wherein the interconnection layer 2000 includes circuit structures CS and first structures ST1, and the substrate 1000 is a mother wafer, which is the substrate before cutting. Subsequently, a polymer layer PL and connection pads CP are further formed on the interconnection layer 2000. Then, a cutting process is performed along the cutting lines CL by a blade BD, for example, cutting through the insulating layers in the interconnection layer 2000 and the substrate 1000, so as to obtain a plurality of semiconductor devices SD as shown in FIG. 1. After the cutting process, a portion of the substrate 1000 and a portion of the interconnection layer 2000 respectively constitute the substrate 100 and the interconnection layer 200 of the semiconductor device SD. The semiconductor device SD may include a semiconductor die. The term “semiconductor die” as referred to in the present disclosure may be a system on a chip (SoC), a central processing unit (CPU), a graphics processing unit (GPU), an application-specific integrated circuit (ASIC), a dynamic random-access memory, a high-bandwidth memory, a photonic integrated circuit, an active component, a passive component, a power management system chip, or other logic integrated circuits. The material of the substrate 1000 may be referred to the above material of the substrate 100.

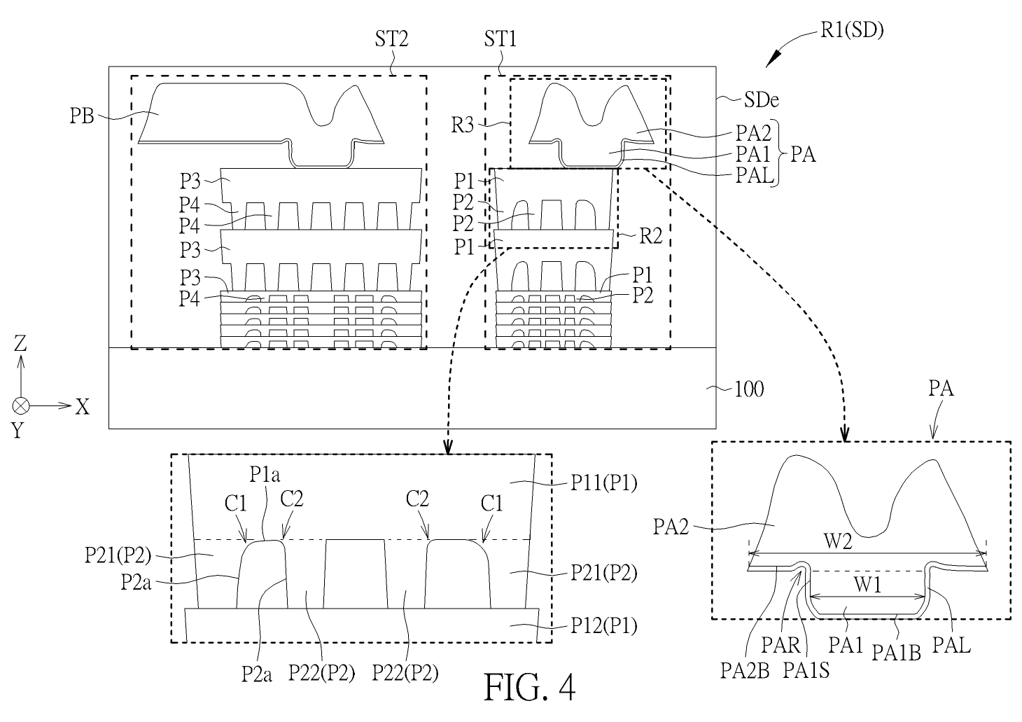

Refer to FIG. 4, in conjunction with FIGS. 1 and 2 , wherein the upper portion of FIG. 4 illustrates an enlarged schematic diagram of the region R1 in FIG. 1, and the lower-left portion and the lower-right portion of FIG. 4 respectively illustrate enlarged schematic diagrams of the region R2 and the region R3 in the upper diagram. As shown in FIG. 4, the first structure ST1 includes a plurality of first portions P1 and a plurality of second portions P2. The plurality of first portions P1 are stacked and arranged along the direction Z (also referred to as a first direction), and the plurality of second portions P2 are disposed between two adjacent ones of the plurality of first portions P1 and arranged along the direction X (also referred to as a second direction). In the cross-sectional view of FIG. 4, each first portion P1 extends along the direction X, and the second portions P2 are disposed between two adjacent first portions P1 in the direction Z or between the lowermost first portion P1 and the substrate 100, and the second portions P2 are spaced apart from each other in the direction X. The second portions P2 and the first portions P1 described above are alternately stacked along the direction Z on the substrate 100 in sequence. Each first portion P1 is formed of at least one conductive layer of the interconnection layer 200, and the second portions P2 disposed between two adjacent first portions P1 are formed of at least another conductive layer of the interconnection layer 200. For example, during the manufacturing process of the semiconductor device SD, one of the conductive layers in the circuit structure CS and at least a portion of the second portions P2 or the first portions P1 may be simultaneously formed on the substrate 100 by the same process (e.g., a photolithography process or an electroplating process), i.e., the conductive layers in the circuit structure CS, the first portions P1 and second portions P2 are formed by the same material and process. The materials of the first portions P1 and the second portions P2 may include copper (Cu) or other suitable conductive materials. In the direction Z, the size and/or component spacing of the first portions P1 and the second portions P2 near the substrate 100 may be smaller than those farther away from the substrate 100, i.e., the fineness of the first portions P1 and the second portions P2 located in lower layers of the interconnection layer 200 is higher than that located in upper layers. For example, the first portion P1 and the second portions P2 located at the lower layer have smaller thicknesses, the width of each of these second portions P2 is smaller, and/or the number of the second portions P2 is greater. From the above, each first portion P1 may be a laterally extending conductive block, and each second portion P2 may be a columnar block, wherein multiple second portions P2 are disposed between two vertically adjacent first portions P1.

In the cross-sectional view of FIG. 4, the first structure ST1 has a first rounded corner C1 located between an inner side surface P1a of one of the first portions P1 and an inner side surface P2a of one of the second portions P2. As shown in the lower-left portion of FIG. 4, a surface of one first portion P11 facing the substrate 100 is defined as the inner side surface P1a, and a surface of one second portion P21 of the second portions P2, which are disposed between the first portion P11 and another adjacent first portion P12, facing another adjacent second portion P22 is defined as the inner side surface P2a. The inner side surface P1a and the inner side surface P2a are connected through the first rounded corner C1. During the cutting process in manufacturing the semiconductor device SD, the first rounded corner C1 is configured to enhance the load-bearing capability of the first structure ST1 under downward pressure during blade cutting, thereby effectively absorbing vibration and reducing the damage to the circuit structure caused when performing the cutting process, so that the quality and reliability of the semiconductor device may be improved. The first structure ST1 may reduce the likelihood of cracks propagating inward from the edge SDe (or the edge of the interconnection layer 200), which could otherwise damage the circuit structure CS.

In this embodiment, the first structure ST1 may further have a second rounded corner C2 located between the inner side surface P1a of the one of the first portions P1 and an inner side surface P2a of another one of the second portions P2. As shown in the lower-left portion of FIG. 4, the inner side surface P1a of the first portion P11 and the inner side surface P2a of another second portion P22 adjacent to the second portion P21 are connected through the second rounded corner C2, wherein the above second portion P21 forming the first rounded corner C1 is the outermost one of the second portions P2 arranged laterally, and a radius of curvature of the first rounded corner C1 is greater than a radius of curvature of the second rounded corner C2. That is to say, the second portion P21 is closest to an edge of the first structure ST1 in direction X among the second portions P2 disposed between two adjacent first portions P1 and/or closest to the edge SDe of the semiconductor device SD or closest to the circuit structure CS. Based on the above structural design, the first rounded corner C1 having a larger curvature radius exists between the outermost second portion P21 and the first portion P11, which may withstand greater downward pressure, so as to reduce damage to the circuit structure caused when performing the cutting process. The outermost second portion P21 closest to the edge SDe is also closest to the cutting line (e.g., the cutting line CL shown in FIG. 3) during the cutting process, and the first rounded corner C1 between this second portion P21 and the first portion P11, having a larger curvature radius, provides better load-bearing capability under downward pressure during blade cutting.

As shown in FIG. 4, the first structure ST1 may further include a pad PA disposed on a top one (i.e., the uppermost one) of the first portions P1. The pad PA includes a first part PA1 and a second part PA2 disposed on the first part PA1, and a width W2 of the second part PA2 is greater than a width W1 of the first part PA1. The pad PA may be a dummy pad or configured for grounding. In the cross-sectional views at the upper and lower-right portions of FIG. 4, the width W1 and the width W2 are obtained by respectively measuring the maximum widths of the first part PA1 and the second part PA2 in the direction X, wherein a junction in the pad PA where the smaller width W1 changes significantly to the larger width W2 is regarded as a boundary distinguishing the first part PA1 from the second part PA2. A bottom surface PA2B of the second part PA2 may include a concave PAR close to a side surface PA1S of the first part PA1. The bottom surface PA2B of the second part PA2 faces the substrate 100 and is recessed at the concave PAR to form a turning corner and adjoin the side surface PA1S of the first part PA1. Through the design of the second part PA2 having the concave PAR, the structure of the pad PA may have improved elasticity, enabling better stress resistance when subjected to downward pressure during blade cutting in the cutting process. As shown in FIG. 4, the pad PA may further include a buffer layer PAL covering a bottom surface PA1B and the side surface PA1S of the first part PA1 and the bottom surface PA2B of the second part PA2, so as to enhance adhesion between the pad PA and the first portion P1. The materials of the first part PA1 and the second part PA2 may include aluminum (Al), and the material of the buffer layer PAL may include titanium (Ti) or tantalum (Ta).

As shown in FIG. 4, and in conjunction with FIGS. 1 and 2 , the interconnection layer 200 may further include a second structure ST2 overlapped with the peripheral region 120 and disposed between the first structure ST1 and the circuit structure CS. In the top view as shown in FIG. 2, the first structure ST1 and the second structure ST2 respectively surround the circuit structure CS, and the second structure ST2 is disposed between the first structure ST1 and the circuit structure CS in the direction X or the direction Y, i.e., the first structure ST1 is closer to the edge SDe of the semiconductor device SD compared to the second structure ST2. As shown in the cross-sectional view at the upper portion of FIG. 4, the second structure ST2 may include a plurality of third portions P3 and a plurality of fourth portions P4, the third portions P3 are arranged in the direction Z, and the fourth portions P4 are disposed between two adjacent ones of the third portions P3 and arranged in the direction X. Each third portion P3 extends along the direction X, and the fourth portions P4 are disposed between two adjacent third portions P3 in the direction Z or between the lowermost third portion P3 and the substrate 100, and the fourth portions P4 are spaced apart from each other in the direction X. The fourth portions P4 and the third portions P3 described above are alternately stacked along the direction Z on the substrate 100 in sequence. Each third portion P3 is formed of at least one conductive layer of the interconnection layer 200, and the fourth portions P4 disposed between two adjacent third portions P3 are formed of at least another conductive layer of the interconnection layer 200. The manufacturing processes and materials of the third portions P3 and the fourth portions P4 may be referred to the first portions P1 and the second portions P2 described above. In the direction Z, the size and/or component spacing of the third portions P3 and the fourth portions P4 near the substrate 100 may be smaller than those farther away from the substrate 100, i.e., the fineness of the third portions P3 and the fourth portions P4 located in lower layers of the interconnection layer 200 may be higher than that located in upper layers. From the above, each third portion P3 may be a laterally extending conductive block, and each fourth portion P4 may be a columnar block, wherein multiple fourth portions P4 are disposed between two vertically adjacent third portions P3. The fourth portion P4 and the second portion P2 may be formed of the same conductive layer, and the third portion P3 and the first portion P1 may be formed of the same conductive layer.

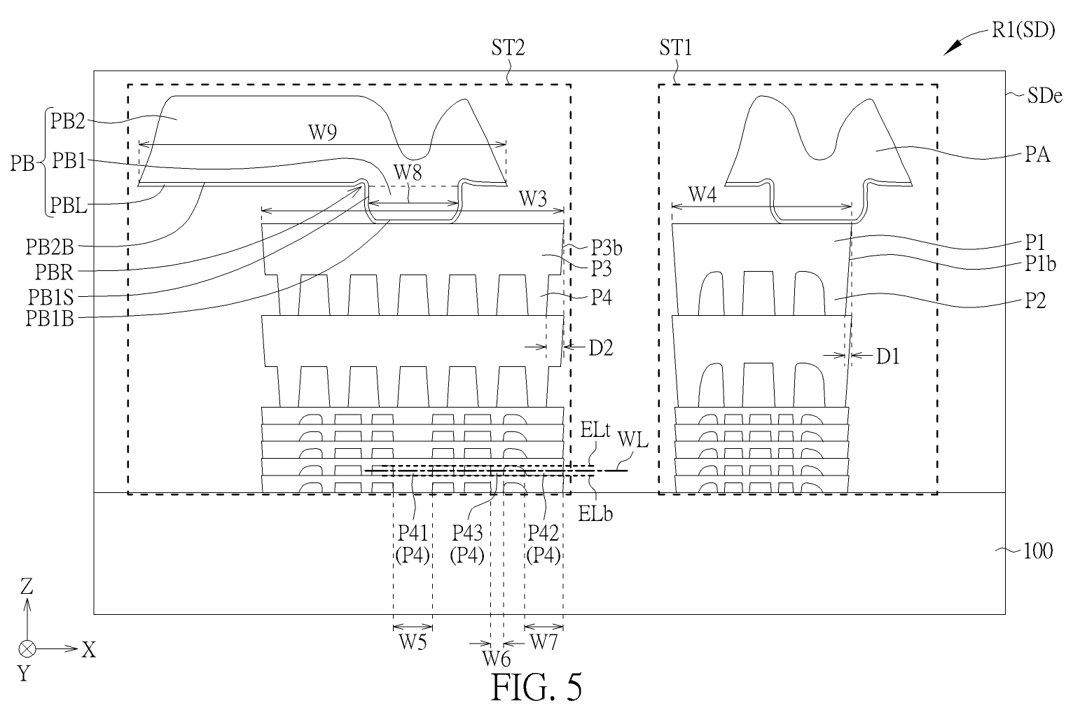

Some detailed structural features of the first structure ST1 and the second structure ST2 of the present disclosure may further be referred to FIG. 5, and in conjunction with FIGS. 1 and 2 , wherein FIG. 5 illustrates an enlarged schematic diagram of the region R1 in FIG. 1 and may correspond to the cross-sectional view at the upper portion of FIG. 4. As shown in FIG. 5, a bottom part of one second portion P2 of the first structure ST1 is spaced apart from an outer side surface P1b of one first portion P1 by a first distance D1, and a bottom part of one fourth portion P4 of the second structure ST2 is spaced apart from an outer side surface P3b of one third portion P3 by a second distance D2, wherein the second distance D2 is greater than the first distance D1. The above outer side surface P1b of the first portion P1 is a surface of the first portion P1 facing the edge SDe of the semiconductor device SD or facing the circuit structure CS, and the above outer surface P3b of the third portion P3 is a surface of the third portion P3 facing the edge SDe or facing the circuit structure CS. In the cross-sectional view shown in FIG. 5, the maximum distance measured along the direction X between the outer side surface P1b of the first portion P1 and the bottom part of the second portion P2 farthest from the first portion P1 is the first distance D1, and the maximum distance measured along the direction X between the outer side surface P3b of the third portion P3 and the bottom part of the fourth portion P4 farthest from the third portion P3 is the second distance D2. A smaller first distance D1 makes the first structure ST1 less likely to sway, so that the first structure ST1 may have better stress resistance during the cutting process, while a larger second distance D2 allows the second structure ST2 to sway laterally, so that the second structure ST2 may have better buffering property during the cutting process. In the direction X, a width W3 of the third portion P3 of the second structure ST2 is greater than a width W4 of the first portion P1 of the first structure ST1, and a total width of the second structure ST2 is greater than a total width of the first structure ST1, so that the second structure ST2 may have better buffering property.

As shown in FIG. 5, in the second structure ST2, the plurality of fourth portions P4 may include a middle fourth portion P41, an outmost fourth portion P42, and a remaining fourth portion P43. The remaining fourth portion P43 is disposed between the middle fourth portion P41 and the outmost fourth portion P42, and a width W5 of the middle fourth portion P41 is greater than a width W6 of the remaining fourth portion P43. A ratio of the width W5 of the middle fourth portion P41 to the width W6 of the remaining fourth portion P43 is greater than or equal to 3 and less than or equal to 10 (i.e., 3 ≤ W5/W6 ≤ 10). The outmost fourth portion P42 is the one closest to the edge SDe of the semiconductor device SD or closest to the circuit structure CS among the fourth portions P4 arranged along the direction X, and the middle fourth portion P41 is located between two outmost fourth portions P42 and at a middle position. One or more remaining fourth portions P43 are disposed between the middle fourth portion P41 and the outmost fourth portion P42 in the direction X. A width W7 of the outmost fourth portion P42 is greater than the width W6 of the remaining fourth portion P43. The width W5, the width W6, and the width W7 may respectively represent the widths of the middle fourth portion P41, the remaining fourth portion P43, and the outmost fourth portion P42 at their middle sections in the direction X. For example, the measurement of the widths W5, W6, and W7 may include: obtaining a top extension line ELt and a bottom extension line ELb respectively passing through the top parts and the bottom parts of the middle fourth portion P41, the outmost fourth portion P42 and the remaining fourth portion P43; obtaining a width measurement line WL at a position midway between the top extension line ELt and the bottom extension line ELb; and measuring the widths of the middle fourth portion P41, the remaining fourth portion P43, and the outmost fourth portion P42 in the direction X along the width measurement line WL. By disposing the middle fourth portion P41 having a larger width W5 as a main support column and the remaining fourth portions P43 having a smaller width W6 as auxiliary support columns in the lower layer near the substrate 100, structural rigidity may be increased to enhance the structural stability of the second structure ST2 having a larger width.

As shown in FIG. 5, the second structure ST2 may further include a pad PB disposed on a top one (i.e., the uppermost one) of the third portions P3. The pad PB includes a first part PB1 and a second part PB2, the second part PB2 is disposed on the first part PB1, and a width W9 of the second part PB2 is greater than a width W8 of the first part PB1. The pad PB may be a dummy pad or configured for grounding. In the cross-sectional view shown in FIG. 5, the width W8 and the width W9 are respectively obtained by measuring the maximum widths of the first part PB1 and the second part PB2 in the direction X, wherein a junction in the pad PB where the smaller width W8 changes significantly to the larger width W9 is regarded as a boundary distinguishing the first part PB1 from the second part PB2. A bottom surface PB2B of the second part PB2 includes a concave PBR close to a side surface PB1S of the first part PB1. The bottom surface PB2B of the second part PB2 faces the substrate 100 and is recessed at the concave PBR to form a turning corner and adjoin the side surface PB1S of the first part PB1. Through the design of the second part PB2 having the concave PBR, the structure of the pad PB may have improved elasticity and better stress resistance. As shown in FIG. 5, the pad PB may further include a buffer layer PBL covering a bottom surface PB1B and the side surface PB1S of the first part PB1 and the bottom surface PB2B of the second part PB2, so as to enhance adhesion between the pad PB and the third portion P3. The materials of the first part PB1 and the second part PB2 may include aluminum, and the material of the buffer layer PBL may include titanium or tantalum.

Referring to FIG. 1, the semiconductor device SD may further include a polymer layer PL, a conductive pad CN and a connection pad CP. The polymer layer PL is disposed on the interconnection layer 200, and the connection pad CP is disposed on the polymer layer PL. The connection pad CP is electrically connected to the conductive pad CN in the circuit structure CS through a via PLV in the polymer layer PL. The polymer layer PL may include an organic material, and the connection pad CP and the conductive pad CN may include copper, tin, nickel, gold, lead, other suitable conductive materials, or combinations of the above materials. The polymer layer PL may be at least partially overlapped with the second structure ST2 in the direction Z, i.e., the polymer layer PL extends from the range of the device region 110 to the peripheral region 120, such that the polymer layer PL, the second structure ST2 and the substrate 100 surround the circuit structure CS to protect the circuit structure CS. For example, in subsequent packaging process of the semiconductor device SD, the crack protection effect of the polymer layer PL for the circuit structure CS may be enhanced. The polymer layer PL may further be at least partially overlapped with the first structure ST1 in the direction Z to protect elements located within the range of the peripheral region 120.

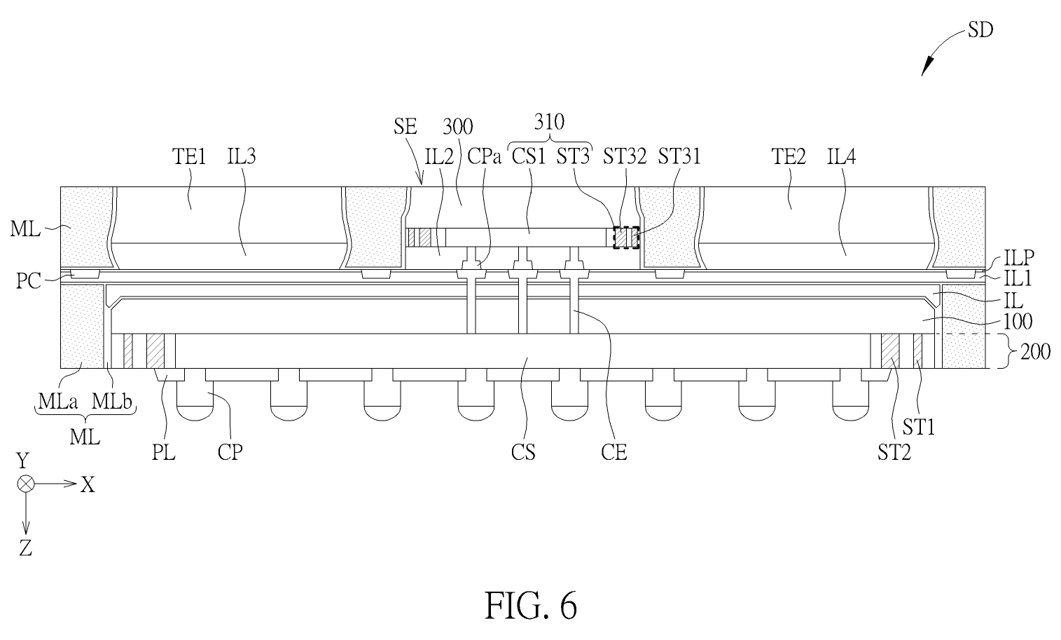

Refer to FIG. 6. As shown in FIG. 6, the semiconductor device SD may further include a semiconductor die SE (referred to as a first semiconductor die in this embodiment) disposed on a side of the substrate 100 away from the interconnection layer 200. The semiconductor die SE includes one or more connection pads CPa (referred to as a first connection pad in this embodiment) electrically connected to the interconnection layer 200. The semiconductor device SD may include an insulating layer IL and an insulating layer IL1 disposed between the substrate 100 and the semiconductor die SE, and the connection pad CPa is electrically connected to the interconnection layer 200 through a connection element CE penetrating the insulating layer IL, the insulating layer IL1 and the substrate 100. The semiconductor die SE may further include a substrate 300 and an interconnection layer 310 (referred to as a first interconnection layer in this embodiment) disposed on a surface of the substrate 300. The interconnection layer 310 includes a circuit structure CS1 (referred to as a first circuit structure in this embodiment) and a third structure ST3, wherein the third structure ST3 is adjacent to the circuit structure CS1, and the third structure ST3 is not overlapped with the connection pad CPa in the direction Z. The third structure ST3 includes a first sub-structure ST31 and a second sub-structure ST32, and their detailed structures may be respectively referred to the first structure ST1 and the second structure ST2 in the foregoing embodiment. Through the structural design in which the third structure ST3 is not overlapped with the connection pad CPa, when the connection pad CPa of the semiconductor die SE is bonded to the connection element CE, the risk of structural fracture caused by stress compression on the third structure ST3 in the direction Z may be reduced. The material of the substrate 300 may be referred to the material of the substrate 100 in the foregoing embodiment. The semiconductor die SE may further include an insulating layer IL2 disposed between the interconnection layer 310 and the insulating layer IL1 in the direction Z.

As shown in FIG. 6, the semiconductor device SD may further include a first structural die TE1 and a second structural die TE2 disposed on a side of the substrate 100 away from the interconnection layer 200. The semiconductor die SE is disposed between the first structural die TE1 and the second structural die TE2. When the connection pad CPa is bonded to the connection element CE, the first structural die TE1 and the second structural die TE2 may be used to balance stress and may further provide a heat dissipation function. An insulating layer IL3 may be disposed between the first structural die TE1 and the insulating layer IL1, and an insulating layer IL4 may be disposed between the second structural die TE2 and the insulating layer IL1. The semiconductor device SD may further include a molding layer ML (or referred to as an encapsulation layer), pads PC, and an insulating layer ILP surrounding the pads PC. The molding layer ML covers side surfaces of the interconnection layer 200 and the substrate 100 and surrounds the first structural die TE1, the semiconductor die SE and the second structural die TE2 to block moisture. The pads PC are disposed between the insulating layer IL1 and the molding layer ML to serve as dummy pads for stress balancing. The insulating layer ILP is disposed on the insulating layer IL1 and covers side surfaces of the pads PC. An interface between the molding layer ML and any one of the first structural die TE1, the semiconductor die SE and the second structural die TE2 may be an uneven surface to provide stress relief in multiple directions. The molding layer ML may include a first molding material MLa and a second molding material MLb. The first molding material MLa has a greater thickness and may include silicon dioxide (SiO₂), and the second molding material MLb has a smaller thickness and may include silicon nitride (SiNx).

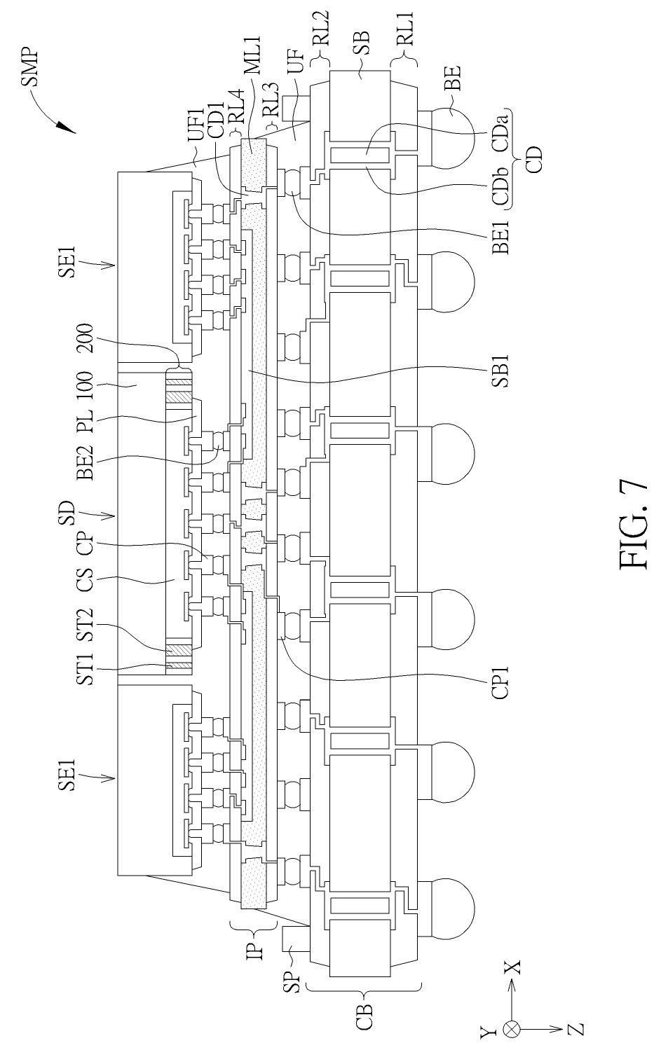

Refer to FIG. 7. As shown in FIG. 7, a semiconductor package SMP includes a circuit substrate CB, an interposer IP, a semiconductor device SD, and a first semiconductor die SE1. The interposer IP is disposed on the circuit substrate CB and includes a first connection pad CP1, and the first connection pad CP1 is bonded on the circuit substrate CB. The first connection pads CP1 are bonded and fixed to a surface of the circuit substrate CB through bonding elements BE1 disposed between the interposer IP and the circuit substrate CB. The semiconductor device SD is disposed on the interposer IP, wherein the semiconductor device SD shown in FIG. 7 is the structure obtained by flipping the semiconductor device SD shown in FIG. 1 upside down, and the layers and components thereof may be referred to the foregoing embodiments. The first semiconductor die SE1 is disposed on the interposer IP and electrically connected to the semiconductor device SD through the interposer IP. The semiconductor device SD and the first semiconductor die SE1 are individually bonded to the interposer IP through bonding elements BE2 disposed on the interposer IP. In the direction Z, the first structure ST1 of the semiconductor device SD is not overlapped with the first connection pad CP1. Therefore, when the first connection pad CP1 of the interposer IP is bonded to the circuit substrate CB, the risk of structural fracture caused by stress compression on the first structure ST1 in the direction Z may be reduced. In the direction Z, the first structure ST1 of the semiconductor device SD is not overlapped with the connection pad CP, so that the risk of structural fracture caused by stress compression during bonding process may be reduced.

As shown in FIG. 7, the circuit substrate CB may include a substrate SB, a redistribution layer RL1 and a redistribution layer RL2 located on opposite sides of the substrate SB, a plurality of conductive structures CD penetrating the substrate SB, and bonding elements BE are disposed on one side of the redistribution layer RL1. The redistribution layer RL2 is electrically connected to the redistribution layer RL1 through the conductive structures CD, and electrically connected to the bonding elements BE through the redistribution layer RL1. The conductive structure CD may include an insulating material CDa filled in a through hole of the substrate SB and a conductive material CDb surrounding the insulating material CDa.

The interposer IP may include one or more substrates SB1, a molding layer ML1 surrounding the substrate SB1, a redistribution layer RL3 and a redistribution layer RL4 located on opposite sides of the molding layer ML1, and conductive structures CD1 penetrating the molding layer ML1, wherein the redistribution layer RL3 includes the first connection pad CP1. The connection pads CP of the semiconductor device SD are bonded to the redistribution layer RL4 through the bonding elements BE2 and electrically connected to the first connection pads CP1 of the redistribution layer RL3 through the redistribution layer RL4 and the conductive structures CD1, and the first connection pads CP1 are bonded to the redistribution layer RL2 of the circuit substrate CB through the bonding elements BE1. The material of the substrate SB1 may be referred to the material of the substrate 100 in the foregoing embodiment.

The first semiconductor die SE1 is electrically connected to the semiconductor device SD through the substrate SB1. The first semiconductor die SE1 is electrically connected to the substrate SB1 through the redistribution layer RL4, and the connection pads CP of the semiconductor device SD are electrically connected to the substrate SB1 through the redistribution layer RL4, such that the first semiconductor die SE1 and the semiconductor device SD are electrically connected to each other via the substrate SB1. As shown in FIG. 7, the semiconductor package SMP includes two first semiconductor dies SE1 disposed on the interposer IP, and the semiconductor device SD is disposed between the two first semiconductor dies SE1 in the direction X. The two first semiconductor dies SE1 may individually be electrically connected to the semiconductor device SD through the substrate SB1.

The semiconductor package SMP may further include an underfill layer UF, a barrier element SP, and an underfill layer UF1. The underfill layer UF covers the first connection pads CP1 and the bonding elements BE1. The barrier element SP is disposed on the redistribution layer RL2 and adjacent to the underfill layer UF to prevent overflow of the underfill layer UF. The underfill layer UF1 covers the connection pads CP and the bonding elements BE2.

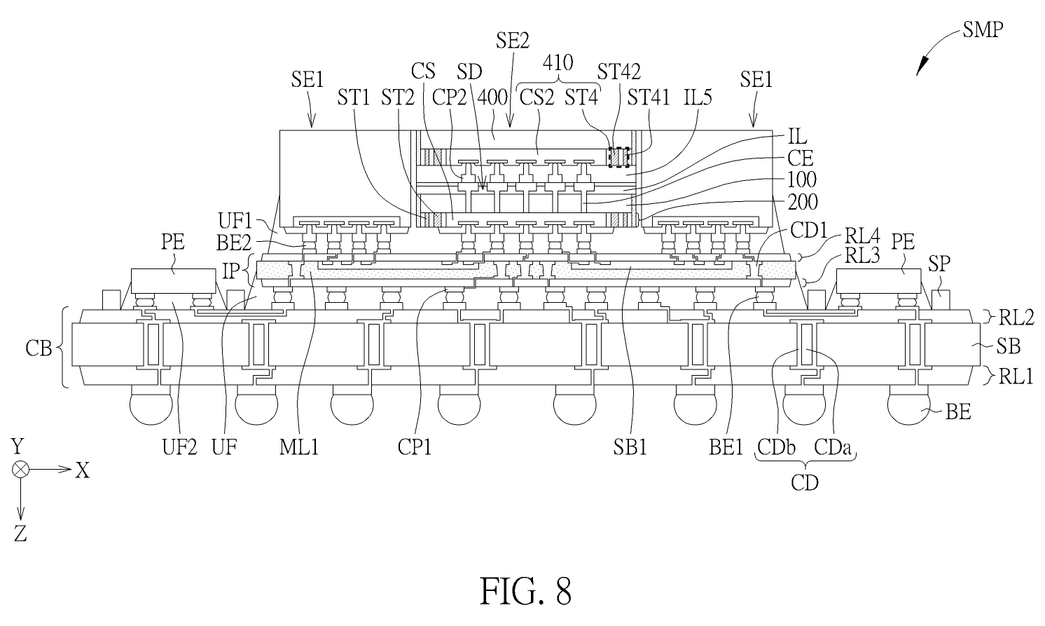

Refer to FIG. 8. A semiconductor package SMP shown in FIG. 8 may further include a second semiconductor die SE2 disposed on the semiconductor device SD. The second semiconductor die SE2 includes one or more second connection pads CP2, and the second connection pad CP2 is directly bonded on and fixed to the semiconductor device SD. In some embodiments, the second connection pad CP2 may be directly bonded to the connection element CE by hybrid bonding. As shown in FIG. 8, the semiconductor device SD may include an insulating layer IL disposed between the substrate 100 and the second semiconductor die SE2, and the second connection pad CP2 is electrically connected to the interconnection layer 200 of the semiconductor device SD through the connection element CE penetrating the insulating layer IL and the substrate 100. The second semiconductor die SE2 may further include a substrate 400 and an interconnection layer 410 disposed on a surface of the substrate 400, and the interconnection layer 410 includes a circuit structure CS2 and a fourth structure ST4, wherein the fourth structure ST4 is adjacent to the circuit structure CS2 and is not overlapped with the first connection pad CP1 in the direction Z. The fourth structure ST4 includes a first sub-structure ST41 and a second sub-structure ST42, and their detailed structures may be respectively referred to the first structure ST1 and the second structure ST2 in the foregoing embodiments. According to the above structural design in which the fourth structure ST4 is not overlapped with the first connection pad CP1, the risk of structural fracture caused by stress compression during bonding process may be reduced. The material of the substrate 400 may be referred to the material of the substrate 100 in the foregoing embodiment. The second semiconductor die SE2 may further include an insulating layer IL5, and the insulating layer IL5 covers a surface of the interconnection layer 410 and side surfaces of the second connection pads CP2. In the direction Z, the fourth structure ST4 of the second semiconductor die SE2 is not overlapped with the second connection pad CP2, so that the risk of structural fracture caused by stress compression during bonding process may be reduced.

As shown in FIG. 8, the semiconductor package SMP may further include one or more passive elements PE disposed on the circuit substrate CB and electrically connected to the circuit substrate CB. The passive element PE may be a capacitor, a resistor, an inductor, or other suitable components. The passive element PE is disposed on the redistribution layer RL2 and electrically connected thereto, and electrically connected to the interposer IP through the redistribution layer RL2. The barrier element SP disposed on the redistribution layer RL2 may be used to prevent overflow of an underfill layer UF2 filled between the passive element PE and the circuit substrate CB.

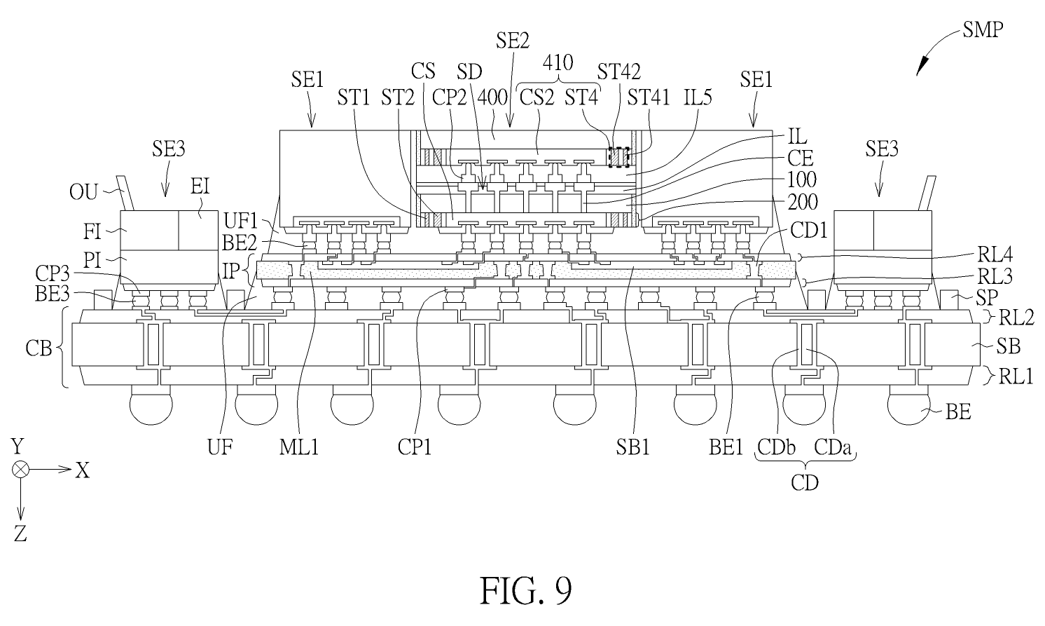

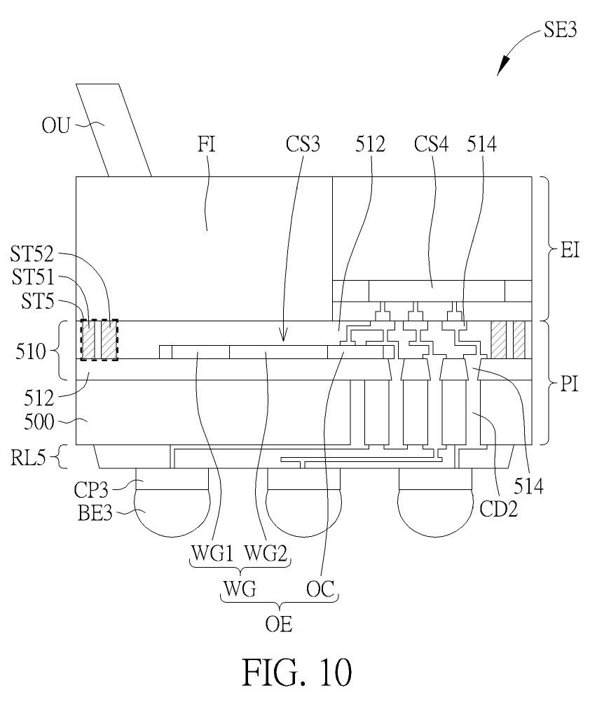

Refer to FIGS. 9 and 10 . A semiconductor package SMP shown in FIGS. 9 and 10 may further include one or more third semiconductor dies SE3 disposed on the circuit substrate CB. The third semiconductor die SE3 may include a photonic integrated circuit (PIC) PI and an electronic integrated circuit (EIC) EI, and the electronic integrated circuit EI is disposed on the photonic integrated circuit PI. The photonic integrated circuit PI includes an optical component OE including a waveguide WG and an optical-to-electrical converter OC. The waveguide WG is configured to receive an optical signal. For example, the waveguide WG may include an optical coupling element WG1 for receiving the optical signal and a light-guiding portion WG2 for guiding the optical signal to the optical-to-electrical converter OC. The optical-to-electrical converter OC is configured to output an electrical signal according to the above optical signal, and the electronic integrated circuit EI is disposed on the optical component OE and configured to receive the electrical signal. The third semiconductor die SE3 may further include a fifth structure ST5 and one or more third connection pads CP3, wherein the third connection pad CP3 is bonded on the circuit substrate CB, and the fifth structure ST5 is not overlapped with the third connection pad CP3 in the direction Z. The fifth structure ST5 includes a first sub-structure ST51 and a second sub-structure ST52, and their detailed structures may be respectively referred to the first structure ST1 and the second structure ST2 in the foregoing embodiments. The third connection pad CP3 is bonded to the redistribution layer RL2 through a bonding element BE3, and electrically connected to the interposer IP through the redistribution layer RL2. According to the structural design in which the fifth structure ST5 is not overlapped with the third connection pad CP3, the risk of structural fracture caused by stress compression during bonding process may be reduced.

As shown in FIG. 10, the photonic integrated circuit PI may include a substrate 500 and an interconnection layer 510 disposed on the substrate 500. The interconnection layer 510 includes a circuit structure CS3 and the fifth structure ST5, wherein the fifth structure ST5 is adjacent to the circuit structure CS3. The material of the substrate 500 may be referred to the material of the substrate 100 in the foregoing embodiment. The circuit structure CS3 includes the optical component OE and at least one insulating layer 512 and at least one conductive layer 514 disposed on the substrate 500 within the interconnection layer 510. The optical-to-electrical converter OC is electrically connected to a circuit structure CS4 of the electronic integrated circuit EI through the conductive layer 514 for signal transmission. The photonic integrated circuit PI may further include a redistribution layer RL5 disposed on a side of the substrate 500 opposite to the interconnection layer 510. The optical-to-electrical converter OC is electrically connected to the redistribution layer RL5 through the conductive layer 514 and conductive structures CD2 penetrating the substrate 500, and electrically connected to the third connection pads CP3 disposed on one side of the redistribution layer RL5.

As shown in FIGS. 9 and 10 , the third semiconductor die SE3 may further include a light-guiding unit OU and a filling layer FI. The filling layer FI is disposed on the photonic integrated circuit PI and located on one side of the electronic integrated circuit EI, and the light-guiding unit OU is disposed on the filling layer FI. The light-guiding unit OU is configured to receive and transmit and guide light, and the light may be transmitted through the filling layer FI to the optical coupling element WG1. The light-guiding unit OU may include optical fibers, and the filling layer FI may include an optical adhesive. In other embodiments, when the photonic integrated circuit PI includes a light-emitting element, the light-guiding unit OU may be configured to transmit and guide light emitted from the photonic integrated circuit PI.

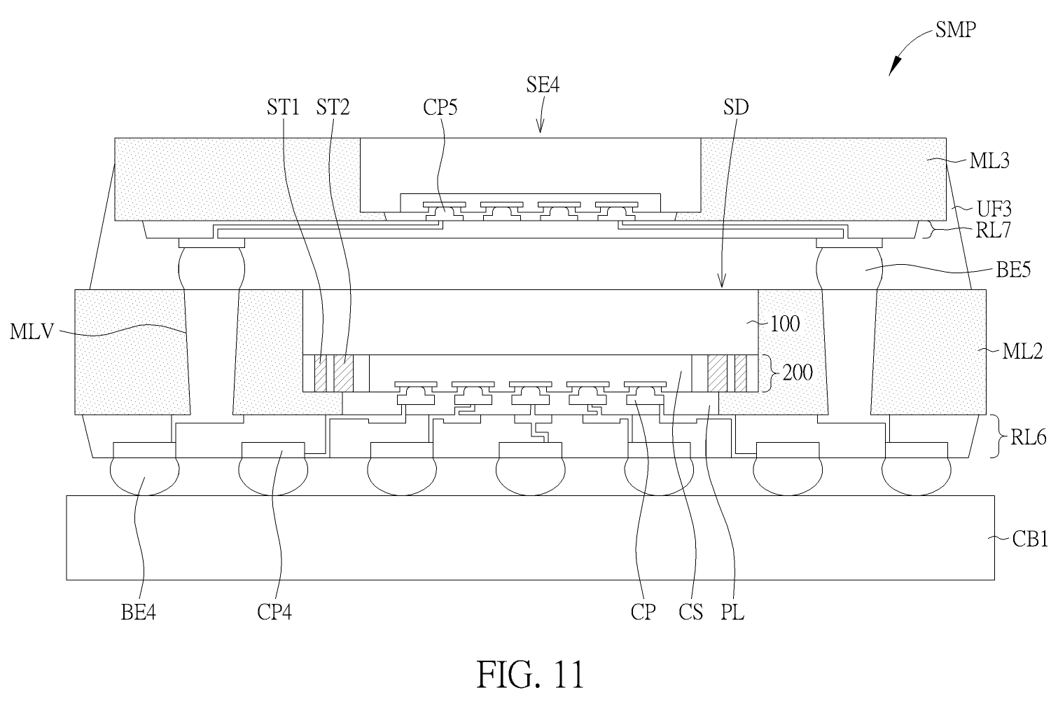

Refer to FIG. 11. As shown in FIG. 11, a semiconductor package SMP may include a semiconductor device SD, a molding layer ML2, a redistribution layer RL6, and a fourth semiconductor die SE4. The detailed structures included in the semiconductor device SD shown in FIG. 11 may be referred to the foregoing embodiments. For example, by flipping the semiconductor device SD shown in FIG. 11 upside down, it may generally correspond to the semiconductor device SD shown in FIG. 1. The molding layer ML2 surrounds the semiconductor device SD. The molding layer ML2 covers side surfaces of the interconnection layer 200 and the substrate 100 to block moisture. The redistribution layer RL6 is disposed on one side of the semiconductor device SD and the molding layer ML2, and the redistribution layer RL6 is electrically connected to the circuit structure CS of the semiconductor device SD, wherein the redistribution layer RL6 includes one or more fourth connection pads CP4. The fourth connection pad CP4 is electrically connected to the connection pad CP of the semiconductor device SD, and electrically connected to the circuit structure CS through the connection pad CP. The fourth semiconductor die SE4 is disposed on a side of the semiconductor device SD away from the redistribution layer RL6 and electrically connected to the redistribution layer RL6 through a via MLV (or referred to as a through hole) in the molding layer ML2. In the direction Z, the first structure ST1 of the semiconductor device SD is not overlapped with the fourth connection pad CP4. According to the structural design in which the first structure ST1 is not overlapped with the fourth connection pad CP4, the risk of structural fracture caused by stress compression during subsequent bonding processes may be reduced. As shown in FIG. 11, the semiconductor package SMP may further include a circuit substrate CB1, wherein the redistribution layer RL6 is disposed on the circuit substrate CB1, and the fourth connection pad CP4 is bonded on the circuit substrate CB1. The fourth connection pad CP4 may be bonded and fixed to a surface of the circuit substrate CB1 through a bonding element BE4. According to the structural design in which the first structure ST1 is not overlapped with the fourth connection pad CP4, the risk of structural fracture in the bonding process of the fourth connection pad CP4 to the circuit substrate CB1 may be reduced. The circuit substrate CB1 may be a printed circuit board (PCB) or other suitable circuit boards. In the direction Z, the second structure ST2 may further be not overlapped with the fourth connection pad CP4 to further reduce the risk of structural fracture.

As shown in FIG. 11, the semiconductor package SMP may further include a redistribution layer RL7 disposed between the fourth semiconductor die SE4 and the semiconductor device SD. A connection pad CP5 of the fourth semiconductor die SE4 is electrically connected to the redistribution layer RL7 and bonded to the via MLV in the molding layer ML2 through a bonding element BE5, and electrically connected to the circuit substrate CB1 through the via MLV and the redistribution layer RL6. The semiconductor package SMP may further include a molding layer ML3 and an underfill layer UF3. The molding layer ML3 surrounds the fourth semiconductor die SE4 to block moisture, and the underfill layer UF3 covers the bonding elements BE5.

From the above description, according to the semiconductor device of the embodiments of the present disclosure, by disposing the first structure and the second structure with specific structural designs in the interconnection layer, the overall structure may have improved downward pressure resistance or may effectively absorb vibration, so as to reduce damage to the circuit structure during the cutting process, thereby enhancing the quality and reliability of the semiconductor device. In addition, by adopting the structural design in which the first structure and the connection pad for bonding do not overlap each other, the risk of structural fracture caused by stress compression may be reduced.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A semiconductor device, comprising:
a substrate comprising a device region and a peripheral region, wherein the peripheral region is adjacent to the device region; and
an interconnection layer disposed on the substrate, the interconnection layer comprising a circuit structure overlapped with the device region and a first structure overlapped with the peripheral region,
wherein the first structure comprises a plurality of first portions arranged in a first direction parallel to a normal direction of the substrate, and a plurality of second portions disposed between two adjacent ones of the first portions and arranged in a second direction perpendicular to the first direction,
wherein in a cross-sectional view, the first structure has a first rounded corner located between an inner side surface of one of the first portions and an inner side surface of one of the second portions.

2. The semiconductor device according to claim 1, wherein the first structure has a second rounded corner located between the inner side surface of the one of the first portions and an inner side surface of another one of the second portions, the one of the second portions is an outmost one of the second portions, and a radius of curvature of the first rounded corner is greater than a radius of curvature of the second rounded corner.

3. The semiconductor device according to claim 1, wherein the first structure further comprises a pad disposed on a top one of the first portions, wherein the pad comprises a first part and a second part disposed on the first part, and a width of the second part is greater than a width of the first part.

4. The semiconductor device according to claim 3, wherein in the cross-sectional view, a bottom surface of the second part comprises a concave, and the concave is close to a side surface of the first part.

5. The semiconductor device according to claim 1, wherein the interconnection layer further comprises a second structure overlapped with the peripheral region and disposed between the first structure and the circuit structure.

6. The semiconductor device according to claim 5, wherein the second structure comprises a plurality of third portions arranged in the first direction, and a plurality of fourth portions disposed between two adjacent ones of the third portions and arranged in the second direction.

7. The semiconductor device according to claim 6, wherein a bottom part of the one of the plurality of second portions is spaced apart from an outer side surface of the one of the plurality of first portions by a first distance, a bottom part of one of the plurality of fourth portions is spaced apart from an outer side surface of one of the plurality of third portion by a second distance, and the second distance is greater than the first distance.

8. The semiconductor device according to claim 6, wherein the plurality of fourth portions comprise a middle fourth portion, an outmost fourth portion and a remaining fourth portion, the remaining fourth portion is disposed between the middle fourth portion and the outmost fourth portion, and a width of the middle fourth portion is greater than a width of the remaining fourth portion.

9. The semiconductor device according to claim 8, wherein a ratio of the width of the middle fourth portion to the width of the remaining fourth portion is greater than or equal to 3 and less than or equal to 10.

10. The semiconductor device according to claim 5, further comprising:
a polymer layer disposed on the interconnection layer; and
a connection pad disposed on the polymer layer, wherein the connection pad is electrically connected to the circuit structure through a via in the polymer layer.

11. The semiconductor device according to claim 10, wherein the polymer layer is at least partially overlapped with the second structure in the first direction.

12. The semiconductor device according to claim 1, further comprising a first semiconductor die disposed on a side of the substrate away from the interconnection layer, wherein the first semiconductor die comprises a first connection pad electrically connected to the interconnection layer.

13. The semiconductor device according to claim 12, wherein the first semiconductor die comprises a first interconnection layer, the first interconnection layer comprises a first circuit structure and a third structure adjacent to the first circuit structure, and the third structure is not overlapped with the first connection pad in the first direction.

14. The semiconductor device according to claim 12, further comprising a first structural die and a second structural die disposed on the side of the substrate away from the interconnection layer, wherein the first semiconductor die is disposed between the first structural die and the second structural die.

15. A semiconductor package, comprising:
a circuit substrate;
an interposer disposed on the circuit substrate and comprising a first connection pad bonded on the circuit substrate;
the semiconductor device as claimed in claim 1 disposed on the interposer; and
a first semiconductor die disposed on the interposer and electrically connected to the semiconductor device through the interposer,
wherein the first structure of the semiconductor device is not overlapped with the first connection pad in the first direction.

16. The semiconductor package according to claim 15, further comprising a second semiconductor die disposed on the semiconductor device, wherein the second semiconductor die comprises a second connection pad directly bonded on the semiconductor device.

17. The semiconductor package according to claim 15, further comprising a third semiconductor die disposed on the circuit substrate, wherein the third semiconductor die comprises:
an optical component comprising a waveguide configured to receive an optical signal and an optical-to-electrical converter configured to output an electrical signal according to the optical signal; and
an electronic integrated circuit disposed on the optical component and configured to receive the electrical signal.

18. The semiconductor package according to claim 17, wherein the third semiconductor die comprises a third structure and a third connection pad bonded on the circuit substrate, and the third structure is not overlapped with the third connection pad in the first direction.

19. A semiconductor package, comprising:
the semiconductor device as claimed in claim 1;
a molding layer surrounding the semiconductor device;
a redistribution layer disposed on a side of the semiconductor device and the molding layer, wherein the redistribution layer is electrically connected to the circuit structure and comprises a fourth connection pad; and
a fourth semiconductor die disposed on a side of the semiconductor device away from the redistribution layer and electrically connected to the redistribution layer through a via in the molding layer,
wherein the first structure of the semiconductor device is not overlapped with the fourth connection pad in the first direction.

20. The semiconductor package according to claim 19, further comprising a circuit substrate on which the redistribution layer is disposed, wherein the fourth connection pad is bonded on the circuit substrate.
